(19) United States
(12) Patent Application Publication
(10) Pub. No.: US 2025/0313708 A1
(43) Pub. Date: Oct. 9, 2025

(54) COMPOSITION FOR BLACK MATRIX, BLACK MATRIX INCLUDING THE COMPOSITION AND DISPLAY DEVICE INCLUDING THE BLACK MATRIX

(71) Applicants: Samsung Display Co., LTD., Yongin-si (KR); DONG YANG Ink Co., Ltd., Pyeongtaek-si (KR)

(72) Inventors: Dong Woon LEE, Yongin-si (KR); Dong Ho KIM, Yongin-si (KR); Ju Suk OH, Yongin-si (KR); Kyong Bin JIN, Yongin-si (KR); Ju Hun LEE, Pyeongtaek-si (KR)

(73) Assignees: Samsung Display Co., LTD., Yongin-si (KR); DONG YANG Ink Co., Ltd., Pyeongtaek-si (KR)

(21) Appl. No.: 18/987,908

(22) Filed: Dec. 19, 2024

(30) Foreign Application Priority Data
Apr. 9, 2024 (KR) 10-2024-0047947

(51) Int. Cl. C09D 11/037; C09D 11/102; C09D 11/107; G02F 1/1335; H10K 59/126

(52) U.S. Cl. CPC C09D 11/037; C09D 11/102; C09D 11/107; G02F 1/133512; H10K 59/126

(57) ABSTRACT

A composition for a black matrix, and a black matrix including the composition and a display device including the black matrix are provided. The composition for a black matrix includes a base resin, regenerated carbon black, a polymer dispersant having an amine value and an acid value of about 5 mgKOH/g or more, respectively, and a curing agent having three or more functional groups.

### CROSS-REFERENCE TO RELATED APPLICATION(S)

This application claims priority to and benefits of Korean Patent Application No. 10-2024-0047947 under 35 U.S.C. § 119 filed on Apr. 9, 2024 in the Korean Intellectual Property Office, the entire contents of which are incorporated herein by reference.

### BACKGROUND

### 1. Technical Field

The disclosure relates to a composition for a black matrix, a black matrix including the composition and a display device including the black matrix.

### 2. Description of the Related Art

A display device is a device that displays an image by using an organic light emitting element or a liquid crystal element. The display device has been applied to TVs, monitors, laptops, tablet PCs, and mobile phones.

The display device may include a window for protecting a display panel. Since mobile phones or tablet PCs can be used while moving without being fixedly installed, they are readily exposed to the external environment, and their window function is more important because they are continuously subjected to an external force in case that a touch function is added. Ink may be printed on an edge portion of such a window, so that a black matrix may be formed in the window. The black matrix may define a non-display area of the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a composition for a black matrix and a method for preparing the same, in which dispersibility and printability are improved.

Another object of the disclosure is to provide a display device comprising a black matrix having improved chemical resistance and wear resistance.

The objects of the disclosure are not limited to those mentioned above and additional objects of the disclosure, which are not mentioned herein, will be clearly understood by those skilled in the art from the following description of the disclosure.

According to an aspect of the disclosure, a composition for a black matrix, the composition may include a base resin; regenerated carbon black; a polymer dispersant having an amine value and an acid value of about 5 mgKOH/g or more, respectively, and a curing agent having three or more functional groups.

In an embodiment, the amine value and acid value of the polymer dispersant may be about 10 mgKOH/g or more and about 50 mgKOH/g or less, respectively.

In an embodiment, a difference between the amine value and the acid value of the polymer dispersant may be about 0.1 mgKOH/g or more and about 20 mgKOH/g or less.

In an embodiment, the polymer dispersant may have a molecular weight of about 4,000 or more and about 25,000 or less.

In an embodiment, a content of the polymer dispersant may be about 1 part by weight or more and about 10 parts by weight or less based on about 100 parts by weight of the base resin.

In an embodiment, the curing agent may have at least one functional group of an isocyanate group and an amine group.

In an embodiment, a content of the curing agent may be about 10 parts by weight or more and about 40 parts by weight or less based on about 100 parts by weight of the base resin.

In an embodiment, the regenerated carbon black may include sulfur, zinc, silica or a combination of sulfur, zinc, and silica.

In an embodiment, the regenerated carbon black may be formed from a waste tire.

In an embodiment, the regenerated carbon black may have an average particle diameter D50 of about 0.1 μm or more and about 5 μm or less.

In an embodiment, the base resin may include an acrylic resin, an epoxy resin or a combination of an acrylic resin, and an epoxy resin.

In an embodiment, the composition may further comprise a sensitizer; a curing accelerator; a photosensitizer; a filler; an antioxidant; an ultraviolet absorber; an anti-aggregation agent; a thermo-polymerization inhibitor; an antifoaming agent; a surfactant; a chain transfer agent; a photo-initiating auxiliary agent; a solvent or a combination.

According to an aspect of the disclosure, a display device may include a window; a black matrix disposed on the window; an adhesive layer disposed on the window, having at least a portion disposed on the black matrix; and a display panel disposed on the adhesive layer, wherein the black matrix may include a base resin, regenerated carbon black, and a polymer dispersant having an amine value and an acid value of about 5 mgKOH/g or more.

In an embodiment, the regenerated carbon black may include sulfur, zinc, silica or their combination.

In an embodiment, the regenerated carbon black may be formed from a waste tire.

In an embodiment, a content of the polymer dispersant may be about 1 part by weight or more and about 10 parts by weight or less based on about 100 parts by weight of the base resin.

In an embodiment, the black matrix may further include a curing agent having three or more functional groups, and a content of the curing agent may be about 10 parts by weight or more and about 40 parts by weight or less based on about 100 parts by weight of the base resin.

In an embodiment, the base resin may include an acrylic resin, an epoxy resin or a combination of acrylic resin and an epoxy resin.

According to an aspect of the disclosure, a method for preparing a composition for a black matrix, the method may include preparing a first ink containing a base resin; regenerated carbon black and a polymer dispersant having an amine value and an acid value, each of which is about 5 mgKOH/g or more, dispersing the first ink; preparing a second ink containing a curing agent having three or more functional groups; and mixing the first ink with the second ink.

In an embodiment, the mixing the first ink with the second ink may include using the second ink of about 5 parts by weight or more and about 20 parts by weight or less relative to the first ink of about 100 parts by weight.

According to an aspect of the disclosure, an electronic device, may include a display device that provides an image, a display device that provides an image, a processor that provides an image data signal to the display device, a memory that stores a data information for operation, and a power module that generates power, wherein the display device comprises, a window; a black matrix disposed on the window; an adhesive layer disposed on the window, having at least a portion disposed on the black matrix; and a display panel disposed on the adhesive layer, wherein the black matrix may include a base resin, regenerated carbon black, and a polymer dispersant having an amine value and an acid value of about 5 mgKOH/g or more.

The composition for a black matrix according to an embodiment may include additives capable of dispersing regenerated carbon black to increase dispersibility.

The display device according to an embodiment may comprise a composition for a black matrix and a black matrix including a cured product of the composition, thereby improving chemical resistance and wear resistance.

Also, regenerated carbon black derived from a waste tire may be used to reduce carbon dioxide emission, and a black matrix including the regenerated carbon black may have chemical resistance and wear resistance properties equal to or greater than those of chemically synthesized carbon black of a comparative example.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view taken along line II-II′ of FIG. 1; and

FIG. 3 is a schematic cross-sectional view illustrating a display device according to an embodiment.

FIG. 4 is a block diagram of an electronic device according to an embodiment of the disclosure.

FIG. 5 is a schematic diagram of an electronic device according to various embodiments of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Each of the features of the various embodiments of the disclosure may be with each other, in part or in whole, and various modifications are possible.

A chemically synthesized black matrix of the comparative example is produced by incomplete combustion of crude oil or gas and is surface-treated to facilitate dispersion, but regenerated carbon black produced by recycling a waste tire is not surface-treated and thus has low dispersibility, thereby making it unsuitable for manufacture of a black matrix.

The chemically synthesized carbon black is obtained by processing crude oil or gas under high temperature and high pressure conditions. However, it is difficult to manufacture carbon black of excellent quality, and carbon dioxide generated during manufacture has been pointed out as a major problem of environmental pollution.

The above environmental pollution problem may be solved by using regenerated carbon black, which is obtained in the process of regenerating a waste tire, instead of the chemically synthesized carbon black of the comparative example, and completed the disclosure by studying a composition combination for a black matrix, which can improve the dispersibility of carbon black.

In an embodiment, the composition for a black matrix may include a base resin, regenerated carbon black, a dispersant having an amine value and an acid value of about 5 mgKOH/g or more, and a curing agent having three or more functional groups.

The base resin may contain an acrylic resin, an epoxy resin or their combination. The base resin may serve to express strength, durability, surface hardness, etc. of a coating film in case that the composition for a black matrix is cured, by controlling a crosslink density in the composition for a black matrix, and to control adhesion to other materials.

The acrylic resin may refer to a polymer compound derived from a monomer containing an acrylate or methacrylate functional group in a molecular structure. The acrylic resin may contain, for example, at least one of alkyl (meta)acrylate, hydroxyalkyl acrylate, polyethylene glycol alkyl ether methacrylate, perfluorinated alkyl (meta)acrylate or silicone (meta)acrylate. In the disclosure, “(meta)acrylate” may mean acrylate or methacrylate. The base resin containing an acrylic resin may contain a hydroxy group in the molecular structure. The acrylic resin may be a polymer resin having a weight-average molecular weight of about 20,000 or more and about 40,000 or less.

The epoxy resin refers to a synthetic resin generated by a ring-opening reaction of a polymer compound containing two or more epoxy groups in a molecule and its epoxy group. For example, the epoxy resin may be a bisphenol A-based epoxy resin or a bisphenol F-based epoxy resin. In an embodiment, the weight-average molecular weight of the epoxy resin may be in a range of about 100 to about 100,000. For example, the weight-average molecular weight of the epoxy resin may be in a range of about 300 to about 10,000. In case that the molecular weight of the epoxy resin is less than about 100, the viscosity of the epoxy resin may be low as an ink composition, and in case that the molecular weight of the epoxy resin exceeds 100,000, the viscosity of the epoxy resin may be too high as the ink composition, whereby it may be difficult to eject the epoxy resin.

The regenerated carbon black may be derived from a waste tire. The regenerated carbon black may be prepared by thermally decomposing the waste tire. The regenerated carbon black may reduce carbon dioxide emission by about 38.5% as compared with the chemically synthesized carbon black of the comparative example, which is prepared from crude oil. The regenerated carbon black may contain a component derived from a waste tire. In an embodiment, the regenerated carbon black may contain sulfur, zinc, silica or their combination.

Since the regenerated carbon black is not surface-treated, its dispersibility may be deteriorated. By optimization of a dispersant or/and other additives, dispersibility of the regenerated carbon black may be improved, and properties of the black matrix may be improved.

An average particle diameter D50 of the regenerated carbon black may be 0.1 μm or more and 5 μm or less. In case that the average particle diameter D50 of the regenerated carbon black exceeds 5 μm, the strength of a cured product of the composition for a black matrix may be deteriorated.

In an embodiment, the composition for a black matrix may include regenerated carbon black of about 10 parts by weight or more and about 50 parts by weight or less based on about 100 parts by weight of the base resin. For example, the composition may include regenerated carbon black of about 20 parts by weight or more and about 40 parts by weight or less or about 30 parts by weight or more and about 40 parts or less by weight or less based on about 100 parts by weight of the base resin. In case that the regenerated carbon black is less than about 10 parts by weight, shielding/light-blocking properties may be deteriorated, and in case that the regenerated carbon black exceeds about 50 parts by weight, the dispersibility of the composition may be low.

The dispersant used together with the regenerated carbon black may be a polymer. In an embodiment, the weight-average molecular weight of the dispersant may be about 4,000 or more and about 25,000 or less. For example, the weight-average molecular weight of the dispersant may be about 8,000 or more and about 10,000 or less. In case that the weight-average molecular weight of the dispersant is less than about 4,000, fluidity of the composition may be increased so that it may be difficult to control ink ejection. In case that the weight-average molecular weight of the dispersant exceeds about 25,000, it may be difficult to disperse the composition.

In an embodiment, the composition for a black matrix may include a dispersant of about 1 part by weight or more and about 10 parts by weight or less based on about 100 parts by weight of the base resin. For example, the dispersant may include about 2 parts by weight or more and about 6 parts by weight or less, or about 4 parts by weight or more and about 5 parts by weight or less based on about 100 parts by weight of the base resin. In case that the dispersant is less than about 1 part by weight, dispersibility of the composition may be low, and in case that the dispersant exceeds about 10 parts by weight, fluidity of the composition may be excessively increased.

The amine value and the acid value of the dispersant may be about 5 mgKOH/g or more, respectively. In case that the amine value and the acid value of the dispersant are about 5 mgKOH/g or more, respectively, it means that the dispersant has a selectable basicity and acidity at the same time. For example, the dispersion stability may be improved by neutralizing charges of the dispersant by compensation for a difference between basicity and acidity. In an embodiment, the amine value and the acid value of the dispersant may be about 10 mgKOH/g or more and about 50 mgKOH/g or less, respectively.

In an embodiment, the amine value of the dispersant may be about 10 mgKOH/g or more and about 50 mgKOH/g or less. By way of example, the amine value of the dispersant may be about 15 mgKOH/g or more and about 40 mgKOH/g or less, or may be about 20 mgKOH/g or more and about 30 mgKOH/g or less. In case that the amine value of the dispersant is less than about 10 mgKOH/g, it is difficult to compensate for acidity, whereby the dispersion stability may be lowered. In case that the amine value exceeds about 50 mgKOH/g, the viscosity of the composition may be excessively increased due to a tangle phenomenon with acid.

In an embodiment, the acid value of the dispersant may be about 10 mgKOH/g or more and about 30 mgKOH/g or less. By way of example, the acid value of the dispersant may be about 10 mgKOH/g or more and about 20 mgKOH/g or less. In case that the acid value of the dispersant is less than about 10 mgKOH/g, it is difficult to compensate for basicity, whereby the dispersion stability may be lowered. In case that the acid value exceeds about 30 mgKOH/g, the viscosity of the composition may be excessively increased due to a tangling phenomenon with base.

In an embodiment, the difference between the amine value and the acid value of the dispersant may be about 0.1 mgKOH/g or more and about 20 mgKOH/g or less. By way of example, the difference may be about 1 mgKOH/g or more and about 17 mgKOH/g or less, or may be about 5 mgKOH/g or more and about 15 mgKOH/g or less. As the above numerical range sufficiently compensates for the difference between basicity and acidity, the dispersion stability may be further improved by neutralizing charges of the dispersant.

The composition for a black matrix may be a mixture of a first ink containing the above-described base resin, regenerated carbon black and dispersant and a second ink containing a curing agent described below.

The curing agent serves to improve coating strength, durability, barrier characteristics and the like by linking the base resin contained in the first ink so that the composition may have a high density. The curing agent may be a polyfunctional agent having three or more functional groups.

The curing agent may have one or more functional groups selected from a group consisting of an isocyanate group and an amine group. In an embodiment, the curing agent may be a block isocyanate oligomer, and may include three or more isocyanate groups. In an embodiment, the curing agent may be a biuret or trimer type isocyanate-based compound. In an embodiment, the curing agent may include three or more amine groups.

The isocyanate-based curing agent of three or more functional groups may be, for example, polymethylene polyphenylisocyanate, triphenylmethane triisocyanate, toluene diisocyanate trimer or trimethylolpropane-modified xylene diisocyanate adduct, but is not limited thereto.

The amine-based curing agent of three or more functional groups may be, for example, diethylenetramine or triethylenetramine.

In an embodiment, the composition for a black matrix may include a curing agent of about 10 parts by weight or more and about 40 parts by weight or less based on about 100 parts by weight of the base resin. For example, the composition may include a curing agent of about 15 parts by weight or more and about 30 parts by weight or less or about 20 parts by weight or more and about 25 parts by weight or less based on about 100 parts by weight of the base resin. In case that the curing agent is less than about 10 parts by weight, crosslinking of the base resin is not sufficient, whereby durability of the cured product may be deteriorated. In case that the curing agent exceeds about 40 parts by weight, the cured product may become vulnerable to heat.

The composition for a black matrix may further include a solvent. The solvent may be contained in the first ink or/and the second ink to adjust a concentration or viscosity. The solvent may be any material capable of dissolving the base resin, the regenerated carbon black, the additive or the like within the spirit and the scope of the disclosure. The solvent may be isophorone, but is not limited thereto.

The composition for a black matrix may further include a sensitizer, a curing accelerator, a photosensitizer, a filler, an antioxidant, an ultraviolet absorber, an anti-aggregation agent, a thermo-polymerization inhibitor, an antifoaming agent, a surfactant, a chain transfer agent, a photo-initiating auxiliary agent, a solvent or their combination additive. The additive may be contained in the above-described first ink. In an embodiment, the composition for a black matrix may further include an antifoaming agent and a filler as additives.

The antifoaming agent destroys air bubbles generated in the composition to prevent appearance defects from occurring in case that forming a coating film, and may be a silicon-based material. A barium sulfate filler is an inert material that adjusts the viscosity of an ink composition and prevents cracks in case that forming a coating film.

In an embodiment, the first ink may contain a base resin, regenerated carbon black, a dispersant, an additive and a solvent. The first ink may contain a base resin of about 30 parts by weight or more and about 70 parts by weight or less, regenerated carbon black of about 5 parts by weight or more and about 30 parts by weight or less, a dispersant of about 1 part by weight or more and about 10 parts by weight or less, an additive of about 5 parts by weight or more and about 30 parts by weight or less, and a solvent of about 10 parts by weight or more and about 50 parts by weight or less, relative to a total weight of about 100 parts by weight. In an embodiment, the first ink may contain a base resin of about 40 parts by weight or more and about 60 parts by weight or less, regenerated carbon black of about 5 parts by weight or more and about 20 parts by weight or less, a dispersant of about 1 part by weight or more and about 5 parts by weight or less, an additive of about 7 parts by weight or more and about 20 parts by weight or more, and a solvent of about 15 parts by weight or more and about 30 parts by weight or less, relative to a total weight of about 100 parts by weight.

The disclosure provides a method for preparing the above-described composition for a black matrix. Each element of the composition is the same as that described above and thus its description will be omitted below.

First, a first ink containing a base resin, regenerated carbon black and a dispersant is prepared. After the base resin and a solvent are added, the dispersant and an antifoaming agent may be added while stirring the base resin and the solvent by a stirrer, and a filler may be added. Afterwards, the regenerated carbon black may be added to prepare the first ink.

Subsequently, the first ink may be dispersed. The first ink may be dispersed at room temperature and normal pressure by using a device such as a 3 roll mill.

A second ink containing the above-described curing agent having three or more functional groups is prepared. In addition to the curing agent, the second ink may contain a solvent for adjusting a concentration or viscosity.

Subsequently, the first ink and the second ink may be mixed with each other. For example, a diluent may be added as necessary. A composition for a black matrix may be prepared by stirring until bubbles disappear. The second ink may be mixed with the first ink in the range of about 5 parts by weight to about 20 parts by weight, relative to about 100 parts by weight of the first ink.

The disclosure provides a composition for the above-described black matrix or a black matrix including a cured product of the composition, and a display device including the above-described black matrix.

The black matrix may include the above-described composition or a cured product thereof. The composition may be photo-cured or thermally cured.

The black matrix may have excellent dispersibility of ink and may have excellent heat resistance and chemical resistance properties even though it may include regenerated carbon black.

Hereinafter, a structure in which a black matrix is applied to a display device will be described in detail. Hereinafter, a display device to which a narrow bezel having a frameless or thin bezel from which a top cover partially covering an upper portion of the display device is removed is applied will be described by way of example, but is not limited thereto.

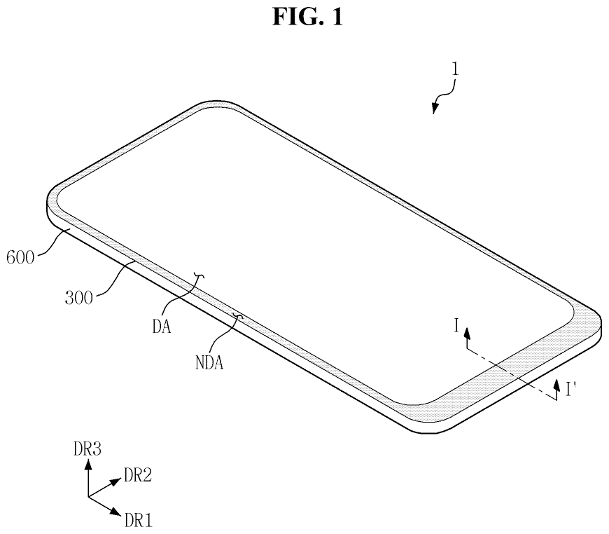

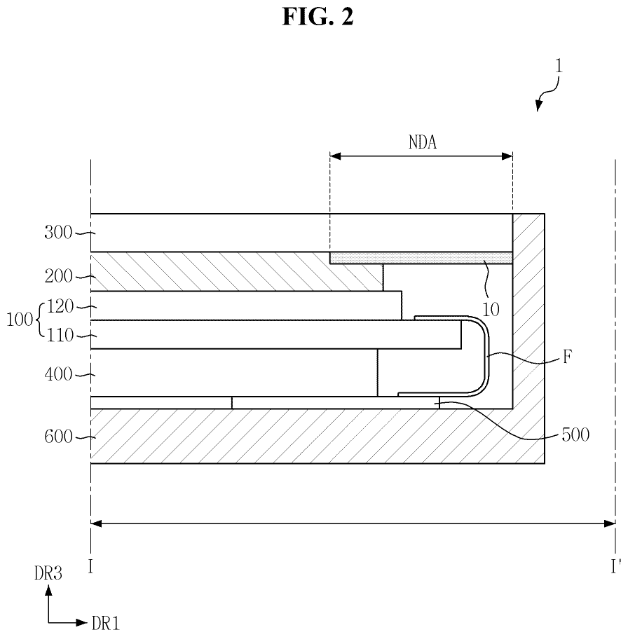

FIG. 1 is a schematic perspective view illustrating a display device according to an embodiment, and FIG. 2 is a schematic cross-sectional view taken along line II-II′ of FIG. 1. FIG. 1 further includes directions DR1, DR2 and DR3 with respect to the display device.

Referring to FIG. 1, a display device 1 may include a window 300 and a chassis 600.

The window 300 may protect the display panel 100 from external impact while allowing an image displayed on the display panel 100 to be visually recognized. In the drawing, a case that the window 300 has a rectangular shape each of which corner is curved on a plane is shown, but the disclosure is not limited thereto.

The window 300 may include a display area DA and a non-display area NDA on a plane. The display area DA is an area in which the image displayed from the display panel 100 is visually recognized, and the non-display area NDA is an area in which the image is not visually recognized. The non-display area NDA is disposed around the display area DA. For example, in case that the display area DA is formed in a rectangular shape, the non-display area NDA may be disposed outside along the edge of the display area DA.

Pixels may be defined in the display area DA. The pixels may be arranged or disposed in the form of a matrix. Signal lines for driving each pixel, for example, gate lines and data lines may be disposed at a boundary of each pixel.

A portion to which a driving chip or an external driving element such as a printed circuit board 500 is connected may be positioned in the non-display area NDA.

The chassis 600 may accommodate elements of the display device 1 including the window 300. The chassis 600 may have a plate shape having a bottom and a sidewall. On a plane, the sidewall of the chassis 600 may be disposed in a shape surrounding the edge of the window 300.

The display device 1 may further include a black matrix 10 disposed on a lower surface of the window 300. The black matrix 10 may be disposed to overlap the non-display area NDA of the window 300 on a plane.

Hereinafter, a cross-sectional structure of the display device 1 including the black matrix 10 will be described in detail with reference to a schematic cross-sectional view taken along line I-I′ of the display device 1 of FIG. 1.

Referring to FIG. 2, the display device 1 may include a chassis 600, a printed circuit board (PCB) 500, a flexible printed circuit board (FPCB) F, a passivation layer 400, a display panel 100, an adhesive layer 200, a window 300 and a black matrix 10.

The chassis 600 is disposed below the display device 1. As described above, the chassis 600 may have a plate shape having a bottom and a sidewall to accommodate elements constituting the display device 1.

The printed circuit board 500 may be disposed on a bottom portion of the chassis 600. The printed circuit board 500 may transfer a driving signal or the like for the display panel 100 to implement an image to the display panel 100 through the flexible circuit board F.

The passivation layer 400 may be disposed on the printed circuit board 500. The passivation layer is a layer for protecting the elements in the display device 1 from external physical and chemical impacts, and may include a cushion layer, a protective film or the like within the spirit and the scope of the disclosure.

The display panel 100 may be disposed on the passivation layer 400. The display panel 100 is an element for implementing an image, and may include a first substrate 110 and a second substrate 120 disposed on the first substrate 110.

The first substrate 110 may be a substrate in which a thin film transistor, which is a switching element, is formed in the form of a matrix. A data line and a gate line may be connected to a source terminal and a gate terminal of the thin film transistor, respectively, and a pixel electrode made of a conductive material may be connected to a drain terminal thereof.

A gate pad and a data pad, which are connected to extended ends of the gate line and the data line, may be disposed in an area corresponding to the non-display area NDA on the plane of the first substrate 110. The gate pad and the data pad may be electrically connected to the printed circuit board 500 through the flexible circuit board F to receive the driving signal and the like within the spirit and the scope of the disclosure.

The second substrate 120 may be disposed to face the first substrate 110. A common electrode made of a conductive material may be formed on the second substrate 120 to face the pixel electrode formed on the first substrate 110. In an embodiment, RGB pixels for implementing colors may be formed on the second substrate 120 in the form of a thin film, but are not limited thereto.

For example, the display panel 100 may further include a display element interposed between the first substrate 110 and the second substrate 120. The display element may be a liquid crystal display element including a liquid crystal layer or an organic light emitting display element including an organic light emitting layer, but is not limited thereto.

In an embodiment, the display panel 100 may further include a touch sensing unit, which is attached thereto or embedded therein, or a polarizing element.

The adhesive layer 200 may be disposed on the display panel 100. The adhesive layer 200 is a layer for fixing the display panel 100 and the window 300 by bonding them to each other, and may include an adhesive resin.

The adhesive resin may include a photo-cured resin. The photo-cured resin may be a material in which a photocurable composition made of a monomer, an oligomer and the like is cured by being polymerized into a polymer by light irradiation of a given wavelength to exert adhesion.

In an embodiment, the photocurable composition may be a material that is cured by ultraviolet (UV) irradiation, but is not limited thereto. In an embodiment, the photocurable composition may be an acrylic compound, a (meth)acrylic compound or the like within the spirit and the scope of the disclosure. In an embodiment, the photocurable composition may further include a photoinitiator that generates free radicals or ions by photo-stimulation such as ultraviolet rays. Examples of the photoinitiator include, but are not limited to, alpha-hydroxyketone, mono- or bisacylphosphine oxide, benzophenone, thioxanthone, ketosulfone, benzyl ketal, phenylglyoxylate, borate, titanosen and oxime ester-based photoinitiators.

In addition to the photo-cured resin, the adhesive resin may include a resin cured by stimulation such as temperature, humidity, physical impact and chemicals, and there is no limitation in types of stimulation that triggers curing in case that the adhesive resin is made of a material cured to have adhesive strength.

The window 300 may be disposed on the adhesive layer 200. The window 300 may be disposed in an area capable of covering the elements in the display device 1, which are accommodated by the chassis 600. As described above, the window 300 may protect the display panel 100 from external impact while allowing the image displayed by the display panel 100 to be visually recognized.

The black matrix 10 may be disposed on the lower surface of the window 300. The black matrix 10 may be disposed to overlap the non-display area NDA of the window 300 on the plane. In an embodiment, the black matrix 10 may be disposed in the same area as the non-display area NDA to completely overlap the non-display area NDA. In an embodiment, the black matrix 10 may define the non-display area NDA.

As described above, the black matrix 10 may include a composition for a black matrix or a cured product thereof.

As at least a portion of the adhesive layer 200 is disposed on the black matrix 10, the adhesive layer 200 may be partially in contact with a surface of the black matrix 10.

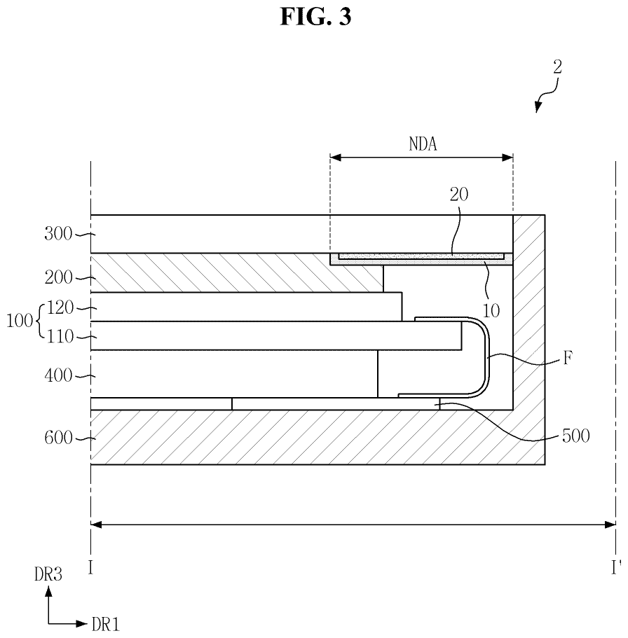

FIG. 3 is a schematic cross-sectional view illustrating a display device according to an embodiment.

A display device 2 of FIG. 3 is the same as that described above with reference to FIG. 2 except that the display device 2 may further include a background color ink layer 20 disposed between the window 300 and the black matrix 10. Hereinafter, a redundant description will be omitted.

Referring to FIG. 3, the background color ink layer 20 may be disposed between the window 300 and the black matrix 10. The black matrix 10 may be disposed to cover at least one surface or a surface of the background color ink layer 20. In the drawing, a structure in which the black matrix 10 is disposed to cover all of a lower surface and sides of the background color ink layer 20 is shown.

The background color ink layer 20 is a layer for implementing the non-display area NDA in a desired color, and the color with the non-display area NDA of the display device 2 is determined depending on a color of ink contained in the background color ink layer 20. The background color ink layer 20 may include, for example, ink such as black, blue, red and white, but is not limited thereto. As the background color ink layer 20 represents a brighter color, for example, the higher brightness is, the thinner a thickness of the black matrix 10 may be. As a result, the black matrix 10 below the background color ink layer 20 may be prevented from being visually recognized, but is not limited thereto.

In case that the durability, heat resistance or chemical resistance of the black matrix 10 is deteriorated, the black matrix 10 may be damaged depending on the usage of the display device 2, and the background color ink layer 20 may be exposed. For example, the background color ink layer 20 may be also damaged, and visibility may be deteriorated. The black matrix 10 having excellent heat resistance and chemical resistance may be formed so that the background color ink layer 20 may be prevented from being damaged.

Hereinafter, a preparation example for preparing the black matrix of the disclosure and experimental examples for evaluating anti-permeability of the black matrix will be described in detail. However, the scope of the disclosure is not limited to the following preparation examples and experimental examples.

### [Preparation and Evaluation of Composition for Black Matrix]

### <Preparation and Evaluation of First Ink>

A first ink containing a dispersant illustrated in Table 1 below was prepared to evaluate a particle diameter D50 and fluidity. Carbon black used in Table 1 below is regenerated carbon black prepared by pyrolysis of a waste tire, and contains zinc (Zn), sulfur(S) and silica (SiO₂).

A base resin of about 45 parts by weight and a solvent of about 27 parts by weight were put into a container of about 2000 cc and stirred, and a dispersant of about 2 parts by weight and an antifoaming agent of about 1 part by weight were added during stirring and a filler of about 10 parts by weight was slowly added to perform stirring for additional about 30 minutes. Afterwards, carbon black was added to perform stirring for additional about 30 minutes, whereby the first ink was prepared.

[Evaluation of particle diameter] After dispersing the first ink five times by using a 3 roll mill, the particle diameter D50 was measured and listed in Table 1 below.

[Evaluation of fluidity] For each composition, the viscosity was measured on a Brookfield viscometer so that a Thixotropic Index (TI) value was calculated as a viscosity index and listed in Table 1 below.

TABLE 1

| | Dispersant | | | | | |
|---|---|---|---|---|---|---|
| | Weight- | Amine | Acid | | | |
| | average | value | value | Particle | | Flu- |
| | molecular | (mg | (mg | diameter | | idity |
| | weight | KOH/g) | KOH/g) | (5 pass) | | (TI) |
| Embodiment | polymer | 20~30 | 10~20 | 5 | μm ↓ | 1~3 |
| 1-1 | (8,000~10,000) | | | | | |
| Comparative | polymer | 5~10 | 0 | 25 | μm ↑ | 5~7 |
| Example 1-1 | (4,000~25,000) | | | | | |
| Comparative | polymer | 10~20 | 0 | 20~25 | μm | 3~5 |
| Example 1-2 | (4,000~25,000) | | | | | |
| Comparative | polymer | 20~30 | 0 | 10~15 | μm | 1~3 |
| Example 1-3 | (4,000~25,000) | | | | | |
| Comparative | polymer | 40~50 | 0 | 5~10 | μm | 1~3 |
| Example 1-4 | (4,000~25,000) | | | | | |
| Comparative | Low molecule | 20~30 | 10~20 | 5 | μm ↓ | 5~7 |
| Example 1-5 | (500~2,000) | | | | | |

Referring to Table 1, it is noted from Embodiment 1-1 that a particle diameter D50 is about 5 μm or less and low fluidity exists even with five dispersion times even in case of regenerated carbon black. A polymer dispersant may include an amine value and an acid value of about 5 mgKOH/g or more, thereby obtaining excellent dispersibility and fluidity suitable for ink printing.

In case that the acid value or the amine value of the dispersant is less than about 5 mgKOH/g or the dispersant is low molecular, it may be seen that dispersibility is lowered or fluidity is high, making it unsuitable for ink printing.

### <Preparation and Evaluation of Composition for Black Matrix>

A first ink was prepared as illustrated in Table 2 below, and a curing agent and a diluent were added to the first ink of about 100 parts by weight and stirred for about 5 minutes to complete a composition for a black matrix. In the preparation of the first ink, the same thing as in the Embodiment 1-1 was used as the dispersant, a silicon-based antifoaming agent of about 1 part by weight and a barium sulfate filler of about 10 parts by weight were used as additives, and isophorone was used as a solvent. In Table 2 below, HMDI means hexamethylene diisocyanate.

After printing on tempered glass with the prepared composition for a black matrix, curing was performed at about 150° C. for about 30 minutes to prepare a black matrix with a thickness of about 5 μm.

TABLE 2

| | | | | | | | Antifoaming |
|---|---|---|---|---|---|---|---|
| | | | | | | | agent |
| | | | | | | | (isocyanate) |
| | First ink | | | | | | Two- |
| | | | Regenerated | | | | functional |
| | Acrylic | Epoxy | carbon | | | | group |
| | resin | Resin | black | Dispersant | Additive | solvent | (HMDI) |
| Embodiment | 45 | | 15 | 2 | 11 | 27 | |
| 2-1 | | | | | | | |
| Embodiment | 45 | | 15 | 2 | 11 | 27 | |
| 2-2 | | | | | | | |
| Embodiment | | 45 | 15 | 2 | 11 | 27 | |
| 2-3 | | | | | | | |
| Comparative | 45 | | 15 | 2 | 11 | 27 | 10 |
| Example 2-1 | | | | | | | |
| Comparative | | 45 | 15 | 2 | 11 | 27 | |
| Example 2-2 | | | | | | | |
| Embodiment | 45 | | 15 | 2 | 11 | 27 | |
| 3-1 | | | | | | | |
| Embodiment | 45 | | 15 | 2 | 11 | 27 | |
| 3-2 | | | | | | | |
| Embodiment | | 45 | 15 | 2 | 11 | 27 | |
| 3-3 | | | | | | | |
| Embodiment | | 45 | 15 | 2 | 11 | 27 | |
| 3-4 | | | | | | | |
| Embodiment | 45 | | 15 | 2 | 11 | 27 | |
| 4-1 | | | | | | | |
| Embodiment | 55 | | 15 | 2 | 11 | 17 | |
| 4-2 | | | | | | | |
| Embodiment | | 45 | 15 | 2 | 11 | 27 | |
| 4-3 | | | | | | | |
| Embodiment | | 55 | 15 | 2 | 11 | 17 | |
| 4-4 | | | | | | | |

| | Antifoaming agent | | | | | |
|---|---|---|---|---|---|---|
| | (isocyanate) | | | | | |
| | Three- | Three- | Antifoaming agent (amine) | | | |
| | functional | functional | Two- | Three- | Features | |
| | group | group | functional | functional | Heat | Chemical |
| | (biuret) | (trimer) | group | group | resistance | resistance |
| Embodiment | 10 | | | | 5B | 376 |
| 2-1 | | | | | | |
| Embodiment | | 10 | | | 5B | 978 |
| 2-2 | | | | | | |
| Embodiment | | | | 10 | 5B | 934 |
| 2-3 | | | | | | |
| Comparative | | | | | 5B | 86 |
| Example 2-1 | | | | | | |
| Comparative | | | 10 | | 5B | 276 |
| Example 2-2 | | | | | | |
| Embodiment | | 10 | | | 5B | 964 |
| 3-1 | | | | | | |
| Embodiment | | 13 | | | 3B | 455 |
| 3-2 | | | | | | |
| Embodiment | | | | 10 | 5B | 923 |
| 3-3 | | | | | | |
| Embodiment | | | | 13 | 3B | 432 |
| 3-4 | | | | | | |
| Embodiment | | 10 | | | 5B | 982 |
| 4-1 | | | | | | |
| Embodiment | | 10 | | | 4B | 487 |
| 4-2 | | | | | | |
| Embodiment | | | | 10 | 5B | 958 |
| 4-3 | | | | | | |
| Embodiment | | | | 10 | 4B | 456 |
| 4-4 | | | | | | |

[Evaluation of Heat Resistance] After printing the composition for a black matrix on a glass substrate, curing was performed at about 150° C. and the composition was left for about 24 hours to prepare a cured product. After immersing the cured product in boiling water for about 2 hours, the cured product was left at room temperature for about 30 minutes. Afterwards, a tape test of ASTM D3359 was performed, and peeling of the cured product from a substrate was confirmed. 5B for a case that there was no peeling at all, 4B for a case that the peeled area was less than about 5%, 3B for a case that the peeled area was about 5% or more and about 15% or less, 2B for a case that the peeled area was greater than about 15% and about 35% or less, 1B for a case that the peeled area was greater than about 35% and about 65% or less and 0B for a case that the peeled area was greater than about 65% were set.

[Evaluation of Chemical Resistance] After printing the composition for a black matrix on a glass substrate, curing was performed at about 150° C. and then the composition was left for about 24 hours. Afterwards, chemical resistance was evaluated by measuring the number of rubbing times in which a printing layer was completely peeled off in case that the printing layer was rubbed using an alcohol rubbing machine by dropping ethanol one drop every two minutes under a load condition of about 1000 g. In case that the number of rubbing times was more than about 300 times, the composition was considered to be excellent in chemical resistance.

In case of Embodiments 4-1 to 4-4, the dispersibility evaluation of the first ink and the resistance of the black matrix were additionally confirmed.

[Evaluation of Dispersibility] The first ink was repeatedly dispersed using a 3 roll mill, and the number of dispersion times with a particle diameter d50 of about 5 μm or less was listed in Table 3 below.

[Evaluation of Resistance] The resistance of the prepared black matrix was measured by applying 1000V to the prepared black matrix through a HIOKI 3454 resistance meter. In case that a resistance value was 1 GQ or more, it was considered that the black matrix has excellent insulation properties.

TABLE 3

| | Dispersibility | Resistance (Ω) |
|---|---|---|
| Embodiment 4-1 | 7PASS | 1 × 10¹² |
| Embodiment 4-2 | 7PASS | 1 × 10¹² |
| Embodiment 4-3 | 7PASS | 1 × 10¹² |
| Embodiment 4-4 | 7PASS | 1 × 10¹² |

Referring to Tables 2 and 3, it may be noted that a black matrix obtained by curing a composition including a polymer dispersant having an amine value and an acid value of about 5 mgKOH/g or more and a curing agent having three or more functional groups has excellent heat resistance and chemical resistance. In Comparative Examples 2-1 and 2-2 in which a curing agent has two functional groups, it may be noted that chemical resistance is significantly deteriorated due to an insufficient cross-linking reaction of a base resin.

It, may be noted that the dispersibility of the first ink, in which a polymer dispersant with an amine value and an acid value of about 5 mgKOH/g is added to regenerated carbon black, is excellent, and that the black matrix obtained by curing a composition including a curing agent of three or more functional groups in the first ink has high resistance and thus has also excellent insulation properties.

The display device according to an embodiment of the disclosure can be applied to various electronic devices. The electronic device according to an embodiment of the disclosure includes the display device described above, and may further include modules or devices having additional functions in addition to the display device.

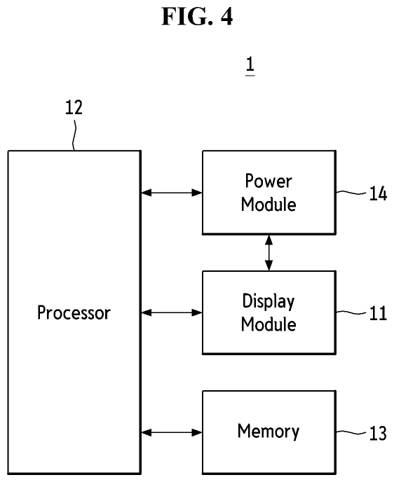

FIG. 4 is a block diagram of an electronic device according to an embodiment of the disclosure.

Referring to FIG. 4, the electronic device 1 according to an embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the an embodiment of the disclosure may be included in the display device 10 according to the embodiments of the disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

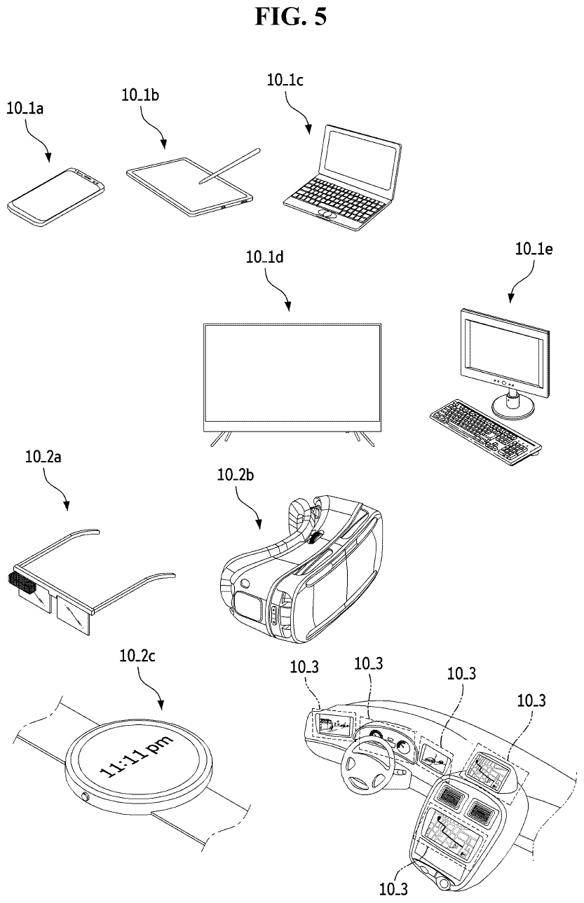

FIG. 5 is a schematic diagram of an electronic device according to various embodiments of the disclosure.

Referring to FIG. 5, various electronic devices to which display devices 10 according to embodiments of the disclosure are applied may include not only image display electronic devices such as a smart phone 10.1a, a tablet PC (personal computer) 10.1b, a laptop 10.1c, a TV 10.1d, and a desk monitor 10.1e, but also wearable electronic devices including display modules such as, for example smart glasses 10.2a, a head mounted display 10.2b, and a smart watch 10.2c, and vehicle electronic devices 10.3 including display modules such as a CID (Center Information Display) and a room mirror display arranged on a dashboard, center fascia, and dashboard of an automobile.

Although the embodiments according to the disclosure have been described with reference to the accompanying drawings, it will be apparent to those skilled in the art that the disclosure can be embodied in other forms without departing from technical spirits and essential characteristics of the disclosure. Thus, the above embodiments are to be considered in all respects as illustrative and not restrictive.

What is claimed is:

1. A composition for a black matrix, the composition comprising:
a base resin;
regenerated carbon black;
a polymer dispersant having an amine value and an acid value of about 5 mgKOH/g or more, respectively; and
a curing agent having three or more functional groups.

2. The composition of claim 1, wherein the amine value and the acid value of the polymer dispersant are about 10 mgKOH/g or more and about 50 mgKOH/g or less, respectively.

3. The composition of claim 1, wherein a difference between the amine value and the acid value of the polymer dispersant is about 0.1 mgKOH/g or more and about 20 mgKOH/g or less.

4. The composition of claim 1, wherein the polymer dispersant has a molecular weight of about 4,000 or more and about 25,000 or less.

5. The composition of claim 1, wherein a content of the polymer dispersant is about 1 part by weight or more and about 10 parts by weight or less based on 100 parts by weight of the base resin.

6. The composition of claim 1, wherein the curing agent has at least one functional group of an isocyanate group and an amine group.

7. The composition of claim 1, wherein a content of the curing agent is about 10 parts by weight or more and about 40 parts by weight or less based on about 100 parts by weight of the base resin.

8. The composition of claim 1, wherein the regenerated carbon black includes sulfur, zinc, silica or a combination of sulfur, zinc, and silica.

9. The composition of claim 8, wherein the regenerated carbon black is formed from a waste tire.

10. The composition of claim 1, wherein the regenerated carbon black has an average particle diameter D50 of about 0.1 μm or more and about 5 μm or less.

11. The composition of claim 1, wherein the base resin includes an acrylic resin, an epoxy resin or a combination of acrylic resin, and an epoxy resin.

12. The composition of claim 1, further comprising:
a sensitizer;
a curing accelerator;
a photosensitizer;
a filler;
an antioxidant;
an ultraviolet absorber;
an anti-aggregation agent;
a thermo-polymerization inhibitor;
an antifoaming agent;
a surfactant;
a chain transfer agent;
a photo-initiating auxiliary agent;
a solvent or a combination.

13. A display device comprising:
a window;
a black matrix disposed on the window;
an adhesive layer disposed on the window, the adhesive layer having at least a portion disposed on the black matrix; and
a display panel disposed on the adhesive layer,
wherein the black matrix uses a base resin, regenerated carbon black, and a polymer dispersant having an amine value and an acid value of about 5 mgKOH/g or more.

14. The display device of claim 13, wherein the regenerated carbon black includes sulfur, zinc, silica or a combination of sulfur, zinc, and silica.

15. The display device of claim 14, wherein the regenerated carbon black is formed from a waste tire.

16. The display device of claim 13, wherein a content of the polymer dispersant is about 1 part by weight or more and about 10 parts by weight or less based on about 100 parts by weight of the base resin.

17. The display device of claim 13, wherein the black matrix further includes a curing agent having three or more functional groups, and a content of the curing agent is about 10 parts by weight or more and about 40 parts by weight or less based on about 100 parts by weight of the base resin.

18. The display device of claim 13, wherein the base resin includes an acrylic resin, an epoxy resin or a combination of acrylic resin, and an epoxy resin.

19. A method for preparing a composition comprising:
preparing a first ink including a base resin, regenerated carbon black and a polymer dispersant having an amine value and an acid value, each of which is about 5 mgKOH/g or more;
dispersing the first ink;
preparing a second ink containing a curing agent having three or more functional groups; and
mixing the first ink with the second ink.

20. The method of claim 19, wherein the mixing of the first ink with the second ink includes using the second ink of about 5 parts by weight or more and about 20 parts by weight or less relative to the first ink of about 100 parts by weight.

21. An electronic device, comprising:
a display device that provides an image;
a processor that provides an image data signal to the display device;
a memory that stores a data information for operation; and
a power module that generates power,
wherein the display device comprises:
a window;
a black matrix disposed on the window;
an adhesive layer disposed on the window, the adhesive layer having at least a portion disposed on the black matrix; and
a display panel disposed on the adhesive layer,
wherein the black matrix uses a base resin, regenerated carbon black, and a polymer dispersant having an amine value and an acid value of about 5 mgKOH/g or more.
